(19) United States
(12) Patent Application Publication
(10) Pub. No.: US 2024/0369895 A1
(43) Pub. Date: Nov. 7, 2024

(54) ACTIVE CANCELLATION OF FREQUENCY NOISE IN LASERS

(71) Applicant: The Board of Trustees of the University of Illinois, Urbana, IL (US)

(72) Inventors: Lintao Li, Champaign, IL (US); Jacob Paul Covey, Savoy, IL (US); William Chiu Wong Huie, Champaign, IL (US); Jia Pern Neville Chen, Champaign, IL (US); Brian Leeds DeMarco, Champaign, IL (US)

(21) Appl. No.: 18/653,068

(22) Filed: May 2, 2024

Related U.S. Application Data
(60) Provisional application No. 63/500,026, filed on May 4, 2023.

(51) Int. Cl. G02F 1/21; G02F 1/11; G02F 1/35; H01S 5/00; H01S 5/14

(52) U.S. Cl. CPC G02F 1/21; G02F 1/113; G02F 1/353; H01S 5/0085; G02F 2201/02; G02F 2203/055; H01S 5/14

(57) ABSTRACT

The present disclosure relates to active cancellation of frequency noise in lasers. One example embodiment includes a device. The device includes an optical cavity exhibiting a resonant optical frequency. The device also includes a laser. An output of the laser is locked to the resonant optical frequency. A first portion of the laser output is transmitted through the optical cavity to filter out high-frequency noise from the first portion of the laser output to generate a modified signal. Additionally, the device includes an acousto-optic modulator configured to generate a reference signal. Further, the device includes a feedforward circuit configured to receive a first portion of the reference signal and generate a feedforward signal. In addition, the device includes an electro-optic modulator configured to interfere a second portion of the reference signal with a second portion of the modified signal using the feedforward signal to generate an output signal.

### CROSS-REFERENCE TO RELATED APPLICATIONS

The present application claims the benefit of U.S. Provisional Patent Application No. 63/500,026, filed May 4, 2023, the contents of which are hereby incorporated by reference.

### BACKGROUND

Unless otherwise indicated herein, the materials described in this section are not prior art to the claims in this application and are not admitted to be prior art by inclusion in this section.

Some laser applications require active frequency stabilization. Some stabilization techniques operate by pushing noise to frequencies outside their bandwidth, leading to large “servo bumps” that can have deleterious effects for certain applications. Some approaches to filtering this noise include passing the laser through a high-finesse optical cavity, which can place undesirable constraints on the system design.

Further, cold atom systems are prevalently used in quantum science applications. Such systems are pushing the limits of laser engineering. Many quantum science applications require long-term frequency stability (sub-Hz), but are also sensitive to the fast-frequency noise (e.g., on the order of MHz). Such stability and fast-frequency noise requirements may, for example, be present when long-lived optical metastable states are needed, such as in optical atomic clocks, quantum computing, quantum simulation, and quantum networking. Likewise, programmable entanglement in atomic clocks for quantum-enhanced precision merges the requirements of optical metrology with quantum computing and networking. Atom-laser coherence at the second scale is required to fully leverage such metastable states, yet short-term stability can still be important (e.g., for gate operations). Further, the use of Rydberg states for programmable entanglement of neutral atoms may also include similar requirements.

### SUMMARY

The specification and drawings disclose embodiments that relate to active cancellation of frequency noise in lasers. According to the techniques described herein, a frequency error signal may be derived from a beat note between the laser and light that passes through a reference cavity. The phase noise derived from this beat note may be fed forward to an electro-optic modulator after the laser (e.g., accounting for relative timing delay) for real-time frequency correction. The techniques described herein may result in (e.g., for a Hz-linewidth laser) an at least 20 dB noise suppression at the peak of the servo bump (e.g., 250 kHz) and a noise suppression bandwidth of about 5 MHz (well beyond the servo bump). Example embodiments may provide a simple and versatile method for obtaining a clean spectrum of a narrow linewidth laser, as may be required in many emerging laser applications (e.g., in cold atom applications), and is compatible with commercial systems (e.g., even those that include wavelength conversion).

In a first aspect, the disclosure describes a device. The device includes an optical cavity exhibiting a resonant optical frequency. The device also includes a laser that is optically coupled to the optical cavity. A first portion of the laser output is transmitted through the optical cavity to filter out high-frequency noise from the first portion of the laser output to generate a modified signal. Additionally, the device includes an acousto-optic modulator configured to interfere a second portion of the laser output with a first portion of the modified signal at a beat frequency to generate a reference signal. Further, the device includes a feedforward circuit configured to receive a first portion of the reference signal and generate a feedforward signal. Generating the feedforward signal includes attenuating frequencies from the first portion of the reference signal that were present in the first portion of the modified signal but not present in the second portion of the laser output. In addition, the device includes an electro-optic modulator configured to interfere a second portion of the reference signal with a second portion of the modified signal using the feedforward signal to generate an output signal.

In a second aspect, the disclosure describes a system. The system includes one or more atoms usable for quantum computing, quantum simulation, or quantum networking. The system also includes a device. The device includes an optical cavity exhibiting a resonant optical frequency. The device also includes a laser that is optically coupled to the optical cavity. An output of the laser is locked to the resonant optical frequency. A first portion of the laser output is transmitted through the optical cavity to filter out high-frequency noise from the first portion of the laser output to generate a modified signal. Additionally, the device includes an acousto-optic modulator configured to interfere a second portion of the laser output with a first portion of the modified signal at a beat frequency to generate a reference signal. Further, the device includes a feedforward circuit configured to receive a first portion of the reference signal and generate a feedforward signal. Generating the feedforward signal includes attenuating frequencies from the first portion of the reference signal that were present in the first portion of the modified signal but not present in the second portion of the laser output. In addition, the device includes an electro-optic modulator configured to interfere a second portion of the reference signal with a second portion of the modified signal using the feedforward signal to generate an output signal. The output signal is used to affect a quantum state of the one or more atoms.

In a third aspect, the disclosure describes a method. The method includes coupling a laser to an optical cavity. The optical cavity exhibits a resonant optical frequency. The method also includes locking an output of the laser to the resonant optical frequency. Additionally, the method includes transmitting a first portion of the laser output through the optical cavity to filter out high-frequency noise from the first portion of the laser output to generate a modified signal. Further, the method includes interfering, by an acousto-optic modulator, a second portion of the laser output with a first portion of the modified signal at a beat frequency to generate a reference signal. In addition, the method includes receiving, by a feedforward circuit, a first portion of the reference signal. Still further, the method includes generating, by the feedforward circuit, a feedforward signal. Generating the feedforward signal includes attenuating frequencies from the first portion of the reference signal that were present in the first portion of the modified signal but not present in the second portion of the laser output. Even further, the method includes interfering, by an electro-optic modulator using the feedforward signal, a second portion of the reference signal with a second portion of the modified signal to generate an output signal.

In a fourth aspect, the disclosure describes a device. The device includes an optical cavity exhibiting a resonant optical frequency. The device also includes a laser configured to output a laser signal. Additionally, the device includes a first modulator configured to modulate a first portion of the laser signal using an offset signal at a beat frequency to generate a modulated signal. The modulated signal is transmitted through the optical cavity to filter out high-frequency noise from the modulated signal to generate a reference signal. The offset signal is locked to the resonant optical frequency. Further, the device includes a feedforward circuit configured to receive the reference signal and generate a feedforward signal. Generating the feedforward signal includes attenuating frequencies from the reference signal that were present in the modulated signal but not present in a second portion of the laser signal that optically bypassed the first modulator and the optical cavity. In addition, the device includes a second modulator configured to modulate a third portion of the laser signal using the feedforward signal to generate an output signal.

The foregoing summary is illustrative only and is not intended to be in any way limiting. In addition to the illustrative aspects, embodiments, and features described above, further aspects, embodiments, and features will become apparent by reference to the figures and the following detailed description.

### BRIEF DESCRIPTION OF THE FIGURES

The patent or application file contains at least one drawing executed in color. Copies of this patent or patent application publication with color drawing(s) will be provided by the Office upon request and payment of the necessary fee.

FIG. 1A is a schematic diagram of device, according to example embodiments.

FIG. 1B is a schematic diagram of a device, according to example embodiments.

FIG. 2A is a high-level schematic diagram of a feedforward circuit, according to example embodiments.

FIG. 2B is a detailed schematic diagram of a portion of a feedforward circuit, according to example embodiments.

FIG. 2C is a detailed schematic diagram of portion of a feedforward circuit, according to example embodiments.

FIG. 3 is a high-level schematic diagram of a feedback circuit, according to example embodiments.

FIG. 4 is a flowchart diagram illustrating a method, according to example embodiments.

FIG. 5A is a plot comparing produced signal spectra, according to example embodiments.

FIG. 5B is a plot comparing simulations of driven two-level atoms, according to example embodiments.

FIG. 6A is a plot comparing devices having different length optical fibers, according to example embodiments.

FIG. 6B is a plot comparing devices having different length optical fibers, according to example embodiments.

FIG. 6C is a plot comparing devices having different properties, according to example embodiments.

FIG. 6D is a plot comparing devices having different properties, according to example embodiments.

FIG. 7 is a plot comparing devices having different properties, according to example embodiments.

FIG. 8A is a plot of simulated results of a portion of a feedforward circuit, according to example embodiments.

FIG. 8B is a plot of simulated results of a portion of a feedforward circuit, according to example embodiments.

FIG. 9 is a schematic diagram of a device, according to example embodiments.

FIG. 10A is a high-level schematic diagram of a Pound Drever Hall (PDH) servo, according to example embodiments.

FIG. 10B is a high-level schematic diagram of a feedforward circuit, according to example embodiments.

FIG. 10C is a high-level schematic diagram of a feedback circuit, according to example embodiments.

FIG. 11 is a detailed schematic diagram of portions of a feedforward circuit, according to example embodiments.

FIG. 12 is a simulation of signal-to-noise ratio (SNR) for the device illustrated in FIG. 9, according to example embodiments.

### DETAILED DESCRIPTION

Example methods and systems are described herein. Any example embodiment or feature described herein is not necessarily to be construed as preferred or advantageous over other embodiments or features. The example embodiments described herein are not meant to be limiting. It will be readily understood that certain aspects of the disclosed systems and methods can be arranged and combined in a wide variety of different configurations, all of which are contemplated herein.

Furthermore, the particular arrangements shown in the figures should not be viewed as limiting. It should be understood that other embodiments might include more or less of each element shown in a given figure. In addition, some of the illustrated elements may be combined or omitted. Similarly, an example embodiment may include elements that are not illustrated in the figures.

### I. OVERVIEW

Example embodiments relate to active cancellation of frequency noise in lasers. Laser noise at the qubit drive frequency (e.g., for quantum computing applications) can be particularly undesirable. For stabilized lasers, broad noise peaks (e.g., from 0.1 MHz to 1 MHz away from the laser frequency), referred to as “servo bumps,” may arise due to finite loop bandwidth. Hence, stabilized lasers with spectral filters that remove this high-frequency noise have been developed, with one approach including an optical cavity as a spectral filter. The optical cavity may be the same cavity to which the laser is stabilized, for example. However, additional gain stages (e.g., injection-locked diode lasers and tapered amplifiers) may be used when using the light transmitted through the optical cavity since the transmitted power (e.g., about 10 μW) may be limited by the power build-up based on the cavity finesse. This limitation may be more pronounced when “ultrahigh” finesse cavities (e.g., having finesse values greater than or equal to 100,000) are used. Additionally, such a cavity transmission technique may be a challenge to implement for laser systems that involve frequency conversion (e.g., second-harmonic generation, which is common for neutral ytterbium, mercury, and cadmium; ionic aluminum, beryllium, and magnesium; and Rydberg transitions of many species).

The techniques described herein provide an alternative approach to spectral filtering of servo bumps based on active noise cancellation via a feedforward technique. By using the cavity-transmitted light to generate a beat note with the laser output, the frequency deviation of the laser output from the cavity-filtered reference can be corrected in real time with an active optical device such as an electro-optic modulator (EOM). In some embodiments, signal delay compensation is also incorporated into the techniques described herein. With optimized signal delay compensation using an optical fiber, example embodiments can suppress noise (e.g., up to approximately 5 MHz away from the original laser output by at least 3 dB below that of the original laser output). Further, using signal delay compensation, the peak of the servo bump (e.g., approximately 250 kHz) may be suppressed (e.g., by up to 22 dB). Additionally, other noise (e.g., noise above 5 MHz away from the original laser output) may remain unaffected (e.g., is not increased) and/or may remain at the level of the original laser. The bandwidth of the noise cancellation may be based, in some embodiments, on the electronic circuitry used to perform the cancellation.

Further, the techniques disclosed herein do not come at the expense of long-term stability (e.g., even in embodiments using a fiber delay line). Additionally, as demonstrated by simulation of the dynamics of a two-level system under a time-dependent drive, example embodiments provide improved results, even when a Rabi frequency near the peak of the servo bump is used. Hence, example embodiments described herein are simple and versatile, provide noise suppression out to high enough bandwidths to be relevant for Rydberg excitation, and can be readily retrofitted to many laser systems that involve both high-finesse cavities and frequency conversion (e.g., complex and/or commercially available laser systems).

### II. EXAMPLE SYSTEMS

The following description and accompanying drawings will elucidate features of various example embodiments. The embodiments provided are by way of example, and are not intended to be limiting. As such, the dimensions of the drawings are not necessarily to scale.

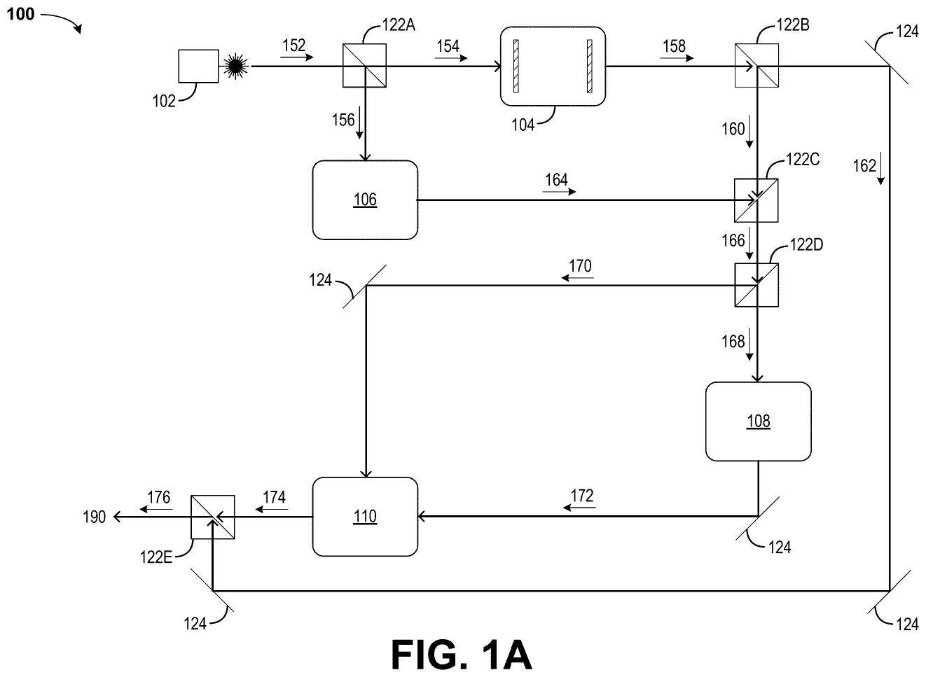

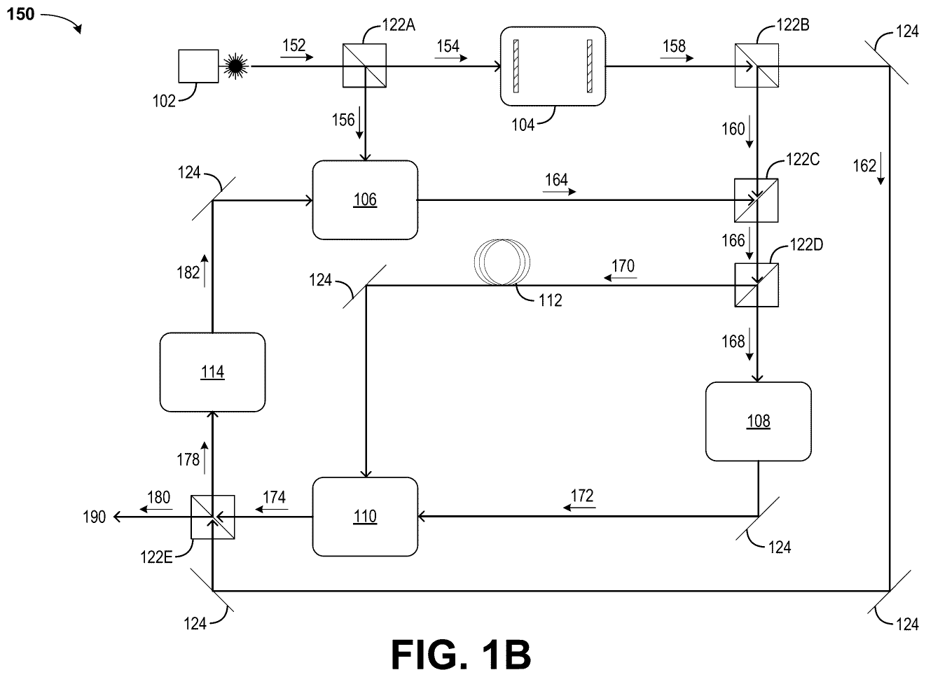

FIG. 1A is a schematic diagram of a device 100, according to example embodiments. The device 100 may include a laser 102, an optical cavity 104, an acousto-optic modulator 106, a feedforward circuit 108, an electro-optic modulator 110, and one or more free-space optics (e.g., beamsplitters 122A, 122B, 122C, 122D, 122E and/or mirrors 124). Although not illustrated, it is understood that other optical components may also be part of the device 100 (e.g., half-wave plates, quarter-wave plates, filters, polarizers, apertures, etc.). Further, additional beamsplitters and/or mirrors and/or alternative locations of beamsplitters 122A, 122B, 122C, 122D, 122E and/or mirrors 124 not illustrated in FIG. 1A may also be included in the device 100 in some embodiments. Each of which is contemplated herein. As illustrated, the components of the device 100 may transmit and receive one or more optical signals from one another as well as modify the optical signal(s). The arrows indicated above, next to, or as part of the components of the device 100 indicate a direction of transmission of the one or more signals. In some embodiments, the device 100 may be a component of a system. For example, the device 100 may be used to generate an output signal which is used to affect a quantum state of one or more atoms of the system (e.g., one or more atoms usable for quantum computing, quantum simulation, or quantum networking).

As illustrated in FIG. 1A, the laser 102 may emit a laser output 152. The laser output 152 may be a light signal with an associated center wavelength/corresponding frequency. In some embodiments, the laser 102 may be an external cavity diode laser (ECDL), such as a TOPTICA PHOTONICS ECDL working at 674 nm for Sr⁺ ions. However, other types of lasers are also possible and are contemplated herein. Further, the laser 102 may be stabilized (e.g., locked) to the optical cavity 104.

The laser output 152 may be transmitted to a beamsplitter 122A. The beamsplitters 122A, 122B, 122C, 122D, 122E pictured in FIG. 1A may be partial beamsplitters or 50:50 beamsplitters, in various embodiments. Further, the beamsplitters 122A, 122B, 122C, 122D, 122E may be cube beamsplitters, plate beamsplitters, polarizing beamsplitters, or non-polarizing beamsplitters. As just one example, some of the beamsplitters 122A, 122B, 122C, 122D, 122E may be a first type of beamsplitter (e.g., a cube beamsplitter) while other beamsplitters 122A, 122B, 122C, 122D, 122E may be a second type of beamsplitter (e.g., a plate beamsplitter). Further, the beamsplitters 122A, 122B, 122C, 122D, 122E may be fabricated using triangular glass prisms, Wollaston prisms, birefringement materials, half-silvered mirrors (e.g., pellicle mirrors), etc. It is noted that, in some embodiments herein, one or more beamsplitters 122A, 122B, 122C, 122D, 122E may be oriented in reverse (e.g., such that the beamsplitters 122A, 122B, 122C, 122D, 122E act as beam combiners).

Upon interaction with beamsplitter 122A, the laser output 152 may be split into a first portion of the laser output 154 and a second portion of the laser output 156. The first portion of the laser output 154 may propagate to and be received by the optical cavity 104. The second portion of the laser output 156 may propagate to and be received by the acousto-optic modulator 106.

As described above, the optical cavity 104 may stabilize (e.g., lock via injection locking) the laser output 152. In addition, the optical cavity 104 may act as a spectral filter (e.g., based on its dimension). For example, the optical cavity 104 may filter out wavelengths from the first portion of the laser output 154 to generate a modified signal 158. In particular, the optical cavity 104 may filter “servo bumps” out of the spectrum of the first portion of the laser output 154. In some embodiments, the optical cavity 104 may have an ultrahigh finesse (e.g., greater than 100,000) and/or a linewidth of less than 10 kHz. Alternatively, the optical cavity 104 may have a high finesse (e.g., about 35,000, such as a cavity from STABLE LASER SYSTEMS that uses the PDH technique) and/or a linewidth around 45 kHz. The modified signal 158 may be transmitted to another beamsplitter 122B. This beamsplitter 122B may split the modified signal 158 into a first portion of the modified signal 160 and a second portion of the modified signal 162. The first portion of the modified signal 160 may be directed to another beamsplitter 122C (e.g., so that the first portion of the modified signal 160 may be interfered with an output from the acousto-optic modulator 106). The second portion of the modified signal 162 may be directed (e.g., using one or more mirrors 124) to another beamsplitter 122E (e.g., so that the second portion of the modified signal 162 may be interfered with an output from the electro-optic modulator 110).

The acousto-optic modulator 106 may receive the second portion of the laser output 156. The acousto-optic modulator 106 may then apply a beat frequency (e.g., between 150 MHz and 250 MHz, such as 200 MHz) to the second portion of the laser output 156 to generate a second portion of the laser output at a beat frequency 164. The acousto-optic modulator 106 may then transmit the second portion of the laser output at the beat frequency 164 to the same beamsplitter 122C as the first portion of the modified signal 160 is being transmitted to. In this way, the acousto-optic modulator 106 may cause the second portion of the laser output 156 to interfere with a first portion of the modified signal 160 at a beat frequency. This interference may result in a reference signal 166 being produced. The reference signal 166 may be transmitted to yet another beamsplitter 122D, resulting in a separation of a first portion of the reference signal 168 from a second portion of the reference signal 170.

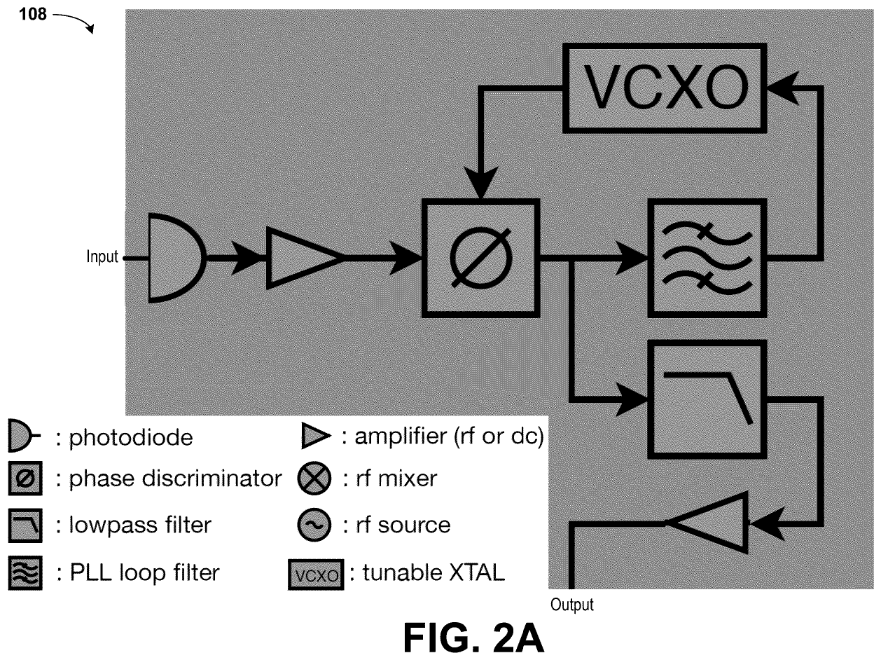

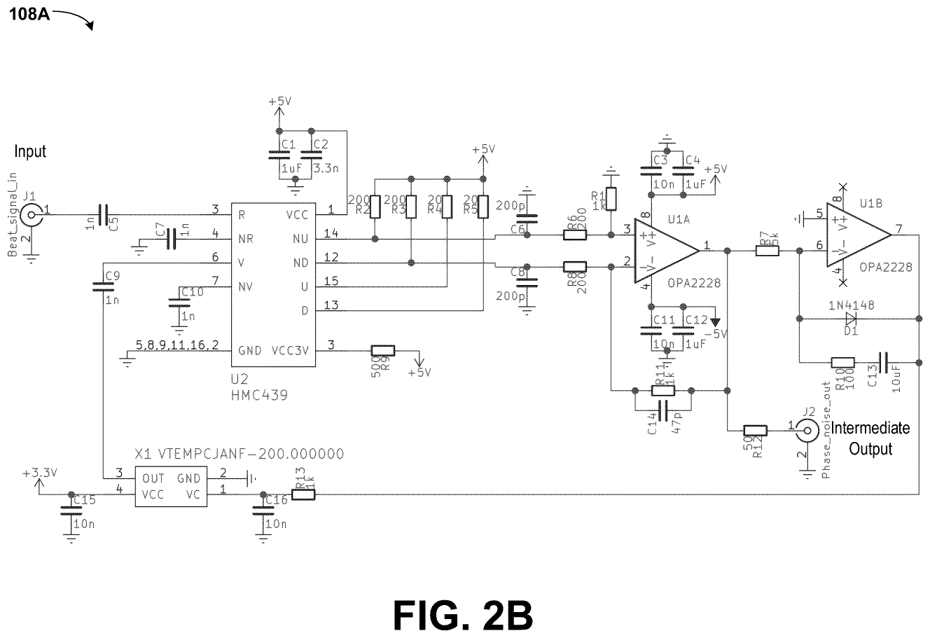

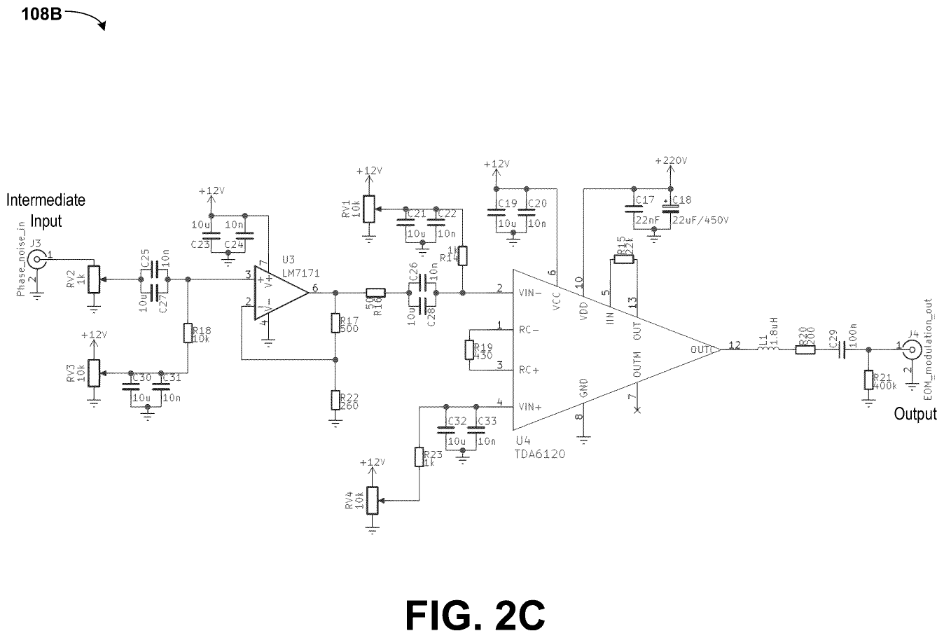

The first portion of the reference signal 168 may be provided to a feedforward circuit 108. The second portion of the reference signal 170 may be provided to an electro-optic modulator 110 (e.g., upon being reflected from one or more mirrors 124). The feedforward circuit 108 (e.g., as described below with reference to FIGS. 2A-2C) may generate a feedforward signal 172 based on the first portion of the reference signal 168. The feedforward signal 172 may correspond to the first portion of the reference signal 168 having frequencies introduced by the optical cavity 104 removed. For example, the feedforward circuit 108 may remove frequencies from the first portion of the reference signal 168 that were in the first portion of the modified signal 160 but not in the second portion of the laser output 156. This may correspond to attenuating only frequencies above 200 Hz, for example. The feedforward circuit 108 may identify which frequencies were in the first portion of the modified signal 160 but not in the second portion of the laser output 156 based on the beat frequency included in the second portion of the laser output at the beat frequency 164. By identifying which frequency components exhibit the beat frequency, the feedforward circuit 108 can isolate and remove such frequency components from the resulting feedforward signal 172.

The electro-optic modulator 110 (e.g., a free-space electro-optic modulator; a cathode-ray tube driver, such as PHILIPS SEMICONDUCTORS TDA6120Q, which has a peak-to-peak voltage output of 160 V with a slew rate of about 10,000 V/μs; or THORLABS EO-AM-NR-C4) may receive the second portion of the reference signal 170 and the feedforward signal 172. Using the feedforward signal 172, the electro-optic modulator 110 may modulate the second portion of the reference signal 170 to generate a modulated second portion of the reference signal 174. As noted above, the modulated second portion of the reference signal 174 (i.e., an output of the electro-optic modulator 110) may be interfered with the second portion of the modified signal 162. Such an interference may occur by directing both the modulated second portion of the reference signal 174 and the second portion of the modified signal 162 to the same beamsplitter 122E. Upon interfering the modulated second portion of the reference signal 174 with the second portion of the modified signal 162, an output signal 176 may be generated. The output signal 176 may be provided (e.g., at a device output 190) to one or more other components. For example, if the device 100 is a component of a quantum system, the output signal 176 may be provided at the device output 190 to one or more cold atoms in order to manipulate one or more quantum states of the cold atom(s).

FIG. 1B is a schematic diagram of a device 150, according to example embodiments. Like, the device 100 illustrated in FIG. 1A, the device 150 may include a laser 102, an optical cavity 104, an acousto-optic modulator 106, a feedforward circuit 108, an electro-optic modulator 110, and one or more free-space optics (e.g., beamsplitters 122A, 122B, 122C, 122D, 122E and/or mirrors 124). Although not illustrated, it is understood that other optical components may also be part of the device 150 (e.g., half-wave plates, quarter-wave plates, filters, polarizers, apertures, etc.). Further, additional beamsplitters and/or mirrors and/or alternative locations of beamsplitters 122A, 122B, 122C, 122D, 122E and/or mirrors 124 not illustrated in FIG. 1B may also be included in the device 150 in some embodiments. Each of which is contemplated herein. As illustrated, the components of the device 150 may transmit and receive one or more optical signals from one another as well as modify the optical signal(s). The arrows indicated above, next to, or as part of the components of the device 150 indicate a direction of transmission of the one or more signals. In some embodiments, the device 150 may be a component of a system. For example, the device 150 may be used to generate an output signal which is used to affect a quantum state of one or more atoms of the system (e.g., one or more atoms usable for quantum computing, quantum simulation, or quantum networking). The description of the components in the device 150 of FIG. 1B that are in common with the components of the device 100 of FIG. 1A may perform similar functions (unless noted below). Hence, for the sake of brevity, those descriptions will not be repeated below with respect to the description of FIG. 1B.

However, unlike the device 100 illustrated in FIG. 1A, the device 150 of FIG. 1B may also include an optical fiber 112 and a feedback circuit 114. As illustrated the optical fiber 112 may be provided prior to the electro-optic modulator 110. For example, the optical fiber 112 (e.g., having a length of about 30 m) may be a part of the path of the second portion of the reference signal 170 prior to the second portion of the reference signal 170 reaching the electro-optic modulator 110. As illustrated in FIG. 1B, the optical fiber 112 may be in a path of the second portion of the reference signal 170 that is parallel with the feedforward circuit 108. Hence, as the feedforward circuit 108 processes the first portion of the reference signal 168, the second portion of the reference signal 170 may propagate through the optical fiber 112. The length of the optical fiber 112 may be selected such that the optical time delay applied to the second portion of the reference signal 170 corresponds to (e.g., is within 25% of, within 10% of, within 5% of, within 1% of, within 0.1% of, or within 0.01% of) an electrical time delay used by the feedforward circuit 108 to process the first portion of the reference signal 168.

Such an optical delay introduced in the optical fiber 112 may help in maintaining phase consistency across the device 150 and/or reducing noise (e.g., cancelling high-frequency noise). However, the introduction of the optical fiber 112 may introduce additional noise (e.g., low-frequency noise) into the device 150 that would otherwise not be present. In order to account for this additional noise, the device 150 may also include the feedback circuit 114. As illustrated in FIG. 1B, the feedback circuit 114 may receive a first portion of the output signal 178 (e.g., the signal labeled as simply the output signal 176 in FIG. 1A). A second portion of the output signal 180 may (like the entire output signal 176 in FIG. 1A) still propagate to the device output 190 (e.g., for external use). The feedback circuit 114 may measure frequency drifts associated with a propagation of the second portion of the reference signal 170 through the optical fiber 112. The feedback circuit 114 may also generate a correction signal 182 based on the measured frequency drifts. Further, the feedback circuit 114 may provide the correction signal 182 to the acousto-optic modulator 106 (e.g., using one or more mirrors 124). To account for the frequency drifts and/or additional noise introduced by the optical fiber 112, the acousto-optic modulator 106 may apply the correction signal 182 when applying the beat frequency to the second portion of the laser output 156.

In some embodiments, the optical fiber 112 may be spooled (e.g., such that an input end of the optical fiber 112 is separated from an output end of the optical fiber 112 by a distance that is less than 10%, less than 5%, less than 1%, less than 0.1%, or less than 0.01% of a total length of the optical fiber 112). In other embodiments, the optical fiber 112 may not be spooled. (e.g., the input end of the optical fiber 112 may be separated from the output end of the optical fiber 112 by a distance that is greater than 10% of the total length of the optical fiber 112). In such embodiments, a reflection from an output end of the optical fiber 112 may be used in an interferometer to generate a correction signal. The correction signal may be used to correct for noise arising from signal propagation through the optical fiber 112.

Some embodiments of the device 100 of FIG. 1A or the device 150 of FIG. 1B may include a frequency multiplier (e.g., a frequency doubler, a frequency quadrupler, a sum frequency mixer, a difference frequency mixer, etc.) configured to apply a multiplication factor to the output signal 176/the second portion of the output signal 180. In such embodiments, the feedforward circuit 108 may apply the multiplication factor to the first portion of the reference signal 168 when generating the feedforward signal 172. When the optical fiber 112 is included in embodiments that include a frequency multiplier, the optical fiber 112 may introduce the time delay upstream of (e.g., prior to) the frequency multiplier applying the multiplication factor to the output signal 176/the second portion of the output signal 180. This may be the case, for example, when generating a final signal having an ultraviolet wavelength using the frequency multiplier (e.g., such that ultraviolet wavelengths do not attempt to propagate through the optical fiber 112).

FIG. 2A is a high-level schematic diagram of the feedforward circuit 108, according to example embodiments. The input signal may captured by a photodiode. The photodiode signal may then be converted to a time-dependent phase deviation, which may be amplified and sent to the electro-optic modulator 110 with proper polarity. The phase locked loop (PLL)-based phase detection circuit may have a working frequency range from about 200 Hz to about 4.8 MHz. The wide band amplifier which drives the electro-optic modulator 110 may have a bandwidth exceeding 15 MHz. The circuitry of the feedforward circuit 108 may introduce an electrical time delay (e.g., of about 140 ns), in some embodiments. As described above, this may be accounted for by introducing the optical fiber 112 into the device 150. In some embodiments, an optical fiber length of 30 m may be used in the optical fiber 112 to introduce an optical time delay that corresponds to the 140 ns electrical time delay.

Besides the delay, the gain of the wide band amplifier of the feedforward circuit 108 may also be considered. The coarse adjustment of the amplifier's gain may be achieved by estimating the sensitivity of the phase discriminator and V_{π} of the electro-optic modulator 110. For fine adjustment, the gain of the amplifier may be tuned by examining the amplitude of the coherent peak.

FIG. 2B is a detailed schematic diagram of a portion of the feedforward circuit 108, according to example embodiments. For example, FIG. 2B may correspond to a first portion 108A of the feedforward circuit 108 shown and described above with reference to FIGS. 1A-2A. The first portion 108A of the feedforward circuit 108 may correspond to a PLL-based phase detection circuit that converts the real-time phase deviation of the input beat signal into voltage.

FIG. 2C is a detailed schematic diagram of portion of the feedforward circuit 108, according to example embodiments. For example, FIG. 2C may correspond to a second portion 108B of the feedforward circuit 108 shown and described above with reference to FIGS. 1A-2A. The second portion 108B of the feedforward circuit 108 may include a high bandwidth and high voltage wideband amplifier that amplifiers the phase deviation signal to high voltage that matches the V_{π} of the electro-optic modulator 110.

As described above, the feedforward circuit may be divided into two parts, the phase measurement circuit (e.g., the first portion 108A) and the driver for the electro-optic modulator 110 (e.g., the second portion 108B). As also described above, the input to the feedforward circuit 108 may include both the high-frequency phase noise from the servo bump and the slow varied phase noise from the acousto-optic modulator 106. The working principle of the phase measurement circuit may be based on using a low bandwidth PLL that tracks the slowly-varying phase noise but ignores the high frequency phase noise. Since the voltage-controlled oscillator tracks the slowly-varying phase noise from the acousto-optic modulator 106, only the servo bump phase noise will appear after the phase detector. An example real-time phase measurement circuit is shown in FIG. 2B. The phase compactor U2 may compare the phase difference between the input beat signal J1 and the output of the voltage controlled crystal oscillator X1. The oscillator X1 may have a very low phase noise and may serve as the reference oscillator for the phase comparison. Thus, the output of U2 may mainly depend on the phase noise of the input beat signal. Since the phase compactor may only work for a phase difference ranging from −π to π, the output of the phase compactor may be fed back to X1 via a slow loop filter formed by U1B. Consequently, the slow fiber noise cancellation servo, the long term phase drifts, and the undesirable phase wraps may not affect the measurement of the phase noise. Finally, the wide band DC amplifier U1A converts the differential output of U2 to a single-ended phase noise voltage signal that is sent to the electro-optic modulator driver circuit (e.g., the second portion 108B of the feedforward circuit 108).

A free-space electro-optic modulator 110 may be used in example embodiments because of its ability to handle high power and its relatively good polarization stability. However, this type of electro-optic modulator 110 may need relatively high driving voltage compared with a waveguide electro-optic modulator 110. A high-speed and high-voltage electro-optic modulator driver may be required to decrease the electrical time delay and/or increase the modulation bandwidth. FIG. 2C illustrates a schematic of an example electro-optic modulator driver (e.g., the second portion 108B of the feedforward circuit 108) according to example embodiments that meets these requirements. One important component is a cathode-ray tube (CRT) driver (PHILIPS SEMICONDUCTOR, TDA6120Q). Such a CRT driver may be traditionally used to drive the cathodes of a CRT in High-Definition televisions or monitors. The amplifier may have been tested up to a peak-to-peak voltage output of 160 V with a slew rate around 10,000 V/μs. An example low-capacitance free-space electro-optic modulator 110 (e.g., THORLABS, EO-AM-NR-C4) with smaller than 20 pF may be used since it is comparable to the capacitance of a CRT cathode. In some embodiments, long distance coax cables may be avoided due to the high parasitic capacitance.

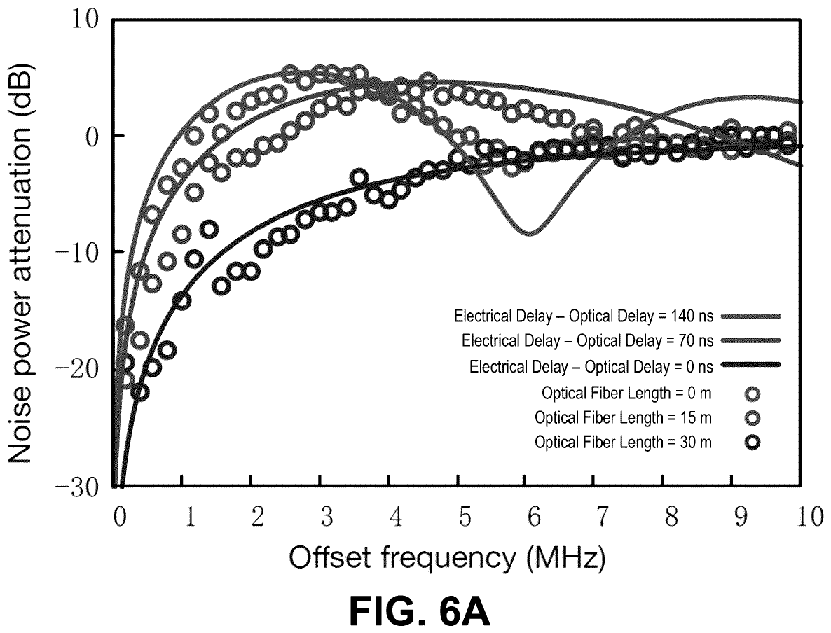

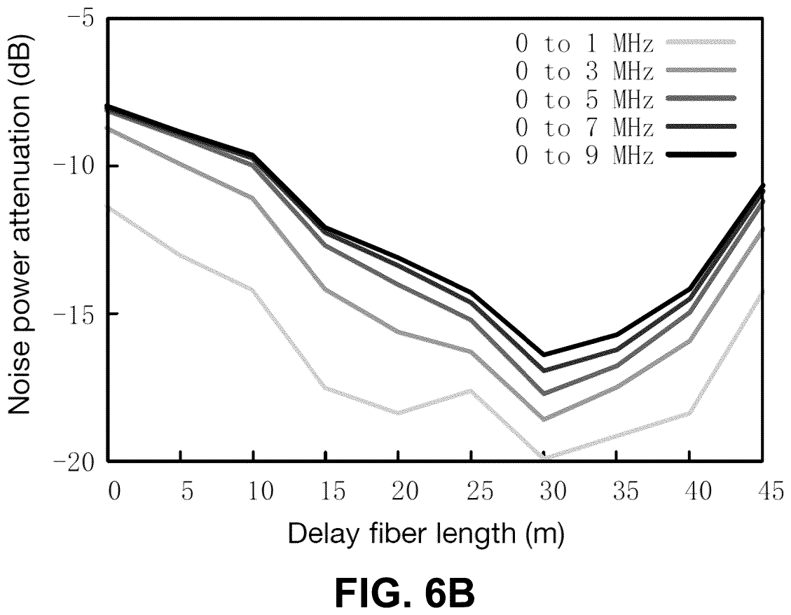

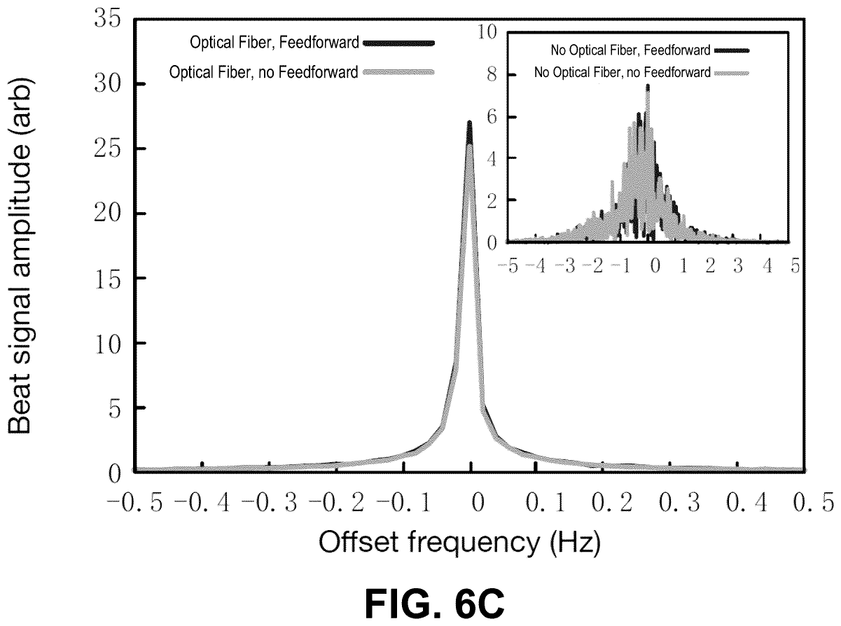

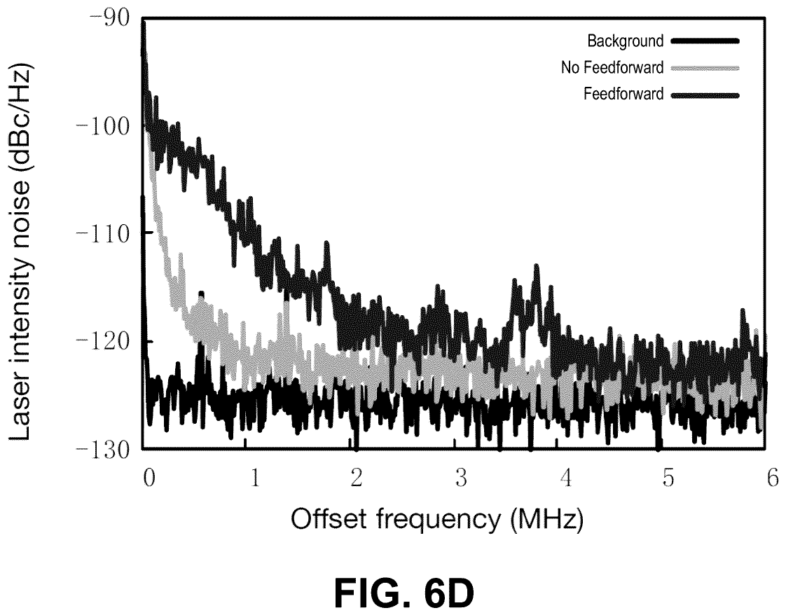

Simulations of the phase calculation circuit were performed based on TINA-TI software, and the voltage-controlled crystal oscillator and the phase detector were replaced with an integrator that gives the same overall transfer function. The simulations indicate a lower frequency response of around 200 Hz and a high frequency response up to 4.8 MHz. For the step response, the simulation gives a bandwidth limited delay of around 130 ns; this delay together with the 10 ns propagation delay in the high voltage amplifier may contribute the overall electrical time delay about 140 ns. The circuit simulation matches the measurement of the noise canceling factor calculated in FIG. 6A (described below).

The physical concept underlying the phase-noise cancellation is the fact that all the noise that is to be removed comes from the feedback system, which is the intrinsic laser phase noise multiplied by the noise gain [1+A(s)]⁻¹ of the feedback loop, where A(s) is the open-loop gain of the system. The function [1+A(s)]⁻¹ may also be known as the noise shaping function that moves the laser phase noise at low frequency up to higher frequency. The information of the phase noise can either be derived from the error signal that modulates the laser frequency or by interfering the laser output with the cavity transmission.

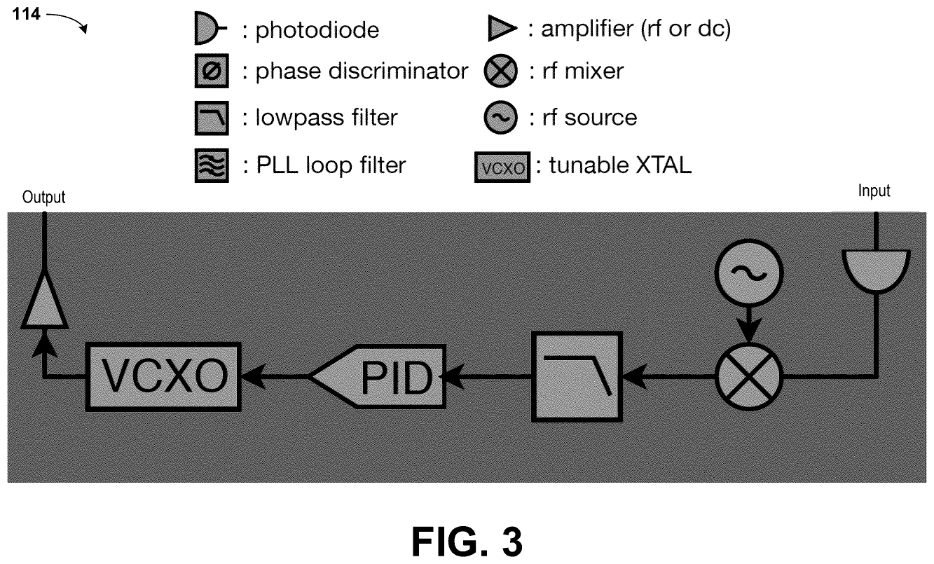

FIG. 3 is a high-level schematic diagram of the feedback circuit 114, according to example embodiments. As illustrated in FIG. 3, a photodiode captures the input into the feedback circuit 114. The captured input (e.g., which includes a 200-MHz signal) may be mixed with a radiofrequency (rf) source of the same frequency in order to create a DC signal. The DC signal may then be used in a proportional-integral-derivative (PID) servo loop with the frequency-tunable rf source that drives the acousto-optic modulator 106. Therefore, the frequency of the laser 102 may be actively adjusted to compensate for the slow, fiber-induced drifts. Due to this fiber noise cancellation, the rf frequency of the acousto-optic modulator 106 may vary relatively slowly with time. Accordingly, the beat signal measured by the feedforward circuit 108 (e.g., by the photodiode describe above with respect to FIG. 2A) may include not only the high-frequency servo bumps from the laser 102, but also slowly-varying phase noise from the acousto-optic modulator 106. Since the feedforward circuit 108 may only respond to phase noise higher than a certain threshold (e.g., 200 Hz), the slow fiber noise cancellation may not adversely affect the function of the feedforward circuit 108. In this way, the long-term stability of the laser 102 obtained by locking it (via feedback) to the optical cavity 104 may be preserved while simultaneously attenuating high frequency, servo-induced noise via feedforward.

### III. EXAMPLE PROCESSES

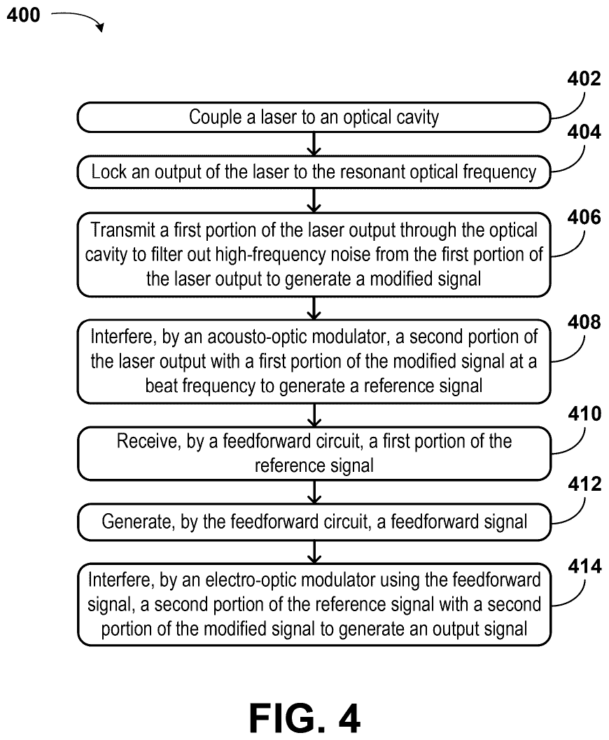

FIG. 4 is a flowchart diagram of a method 400, according to example embodiments. In some embodiments, the method 400 may be performed by a device (e.g., the device 100 shown and described with reference to FIG. 1A or the device 150 shown and described with reference to FIG. 1B).

At block 402, the method 400 may include coupling a laser to an optical cavity. The optical cavity may exhibit a resonant optical frequency.

At block 404, the method 400 may include locking an output of the laser to the resonant optical frequency.

At block 406, the method 400 may include transmitting a first portion of the laser output through the optical cavity to filter out high-frequency noise from the first portion of the laser output to generate a modified signal.

At block 408, the method 400 may include interfering, by an acousto-optic modulator, a second portion of the laser output with a first portion of the modified signal at a beat frequency to generate a reference signal.

At block 410, the method 400 may include receiving, by a feedforward circuit, a first portion of the reference signal.

At block 412, the method 400 may include generating, by the feedforward circuit, a feedforward signal. Generating the feedforward signal comprises attenuating frequencies from the first portion of the reference signal that were present in the first portion of the modified signal but not present in the second portion of the laser output.

At block 414, the method 400 may include interfering, by an electro-optic modulator using the feedforward signal, a second portion of the reference signal with a second portion of the modified signal to generate an output signal.

### IV. EXPERIMENTAL AND SIMULATION RESULTS

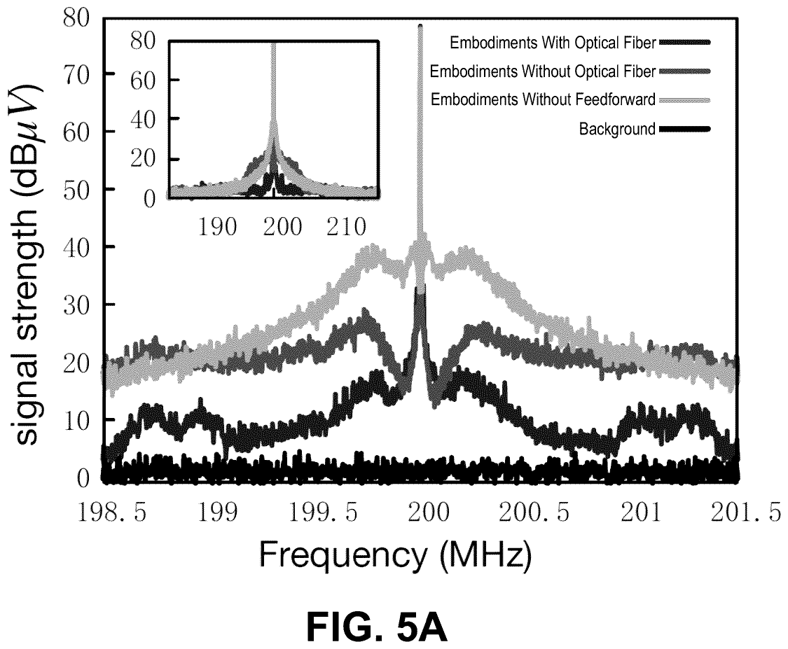

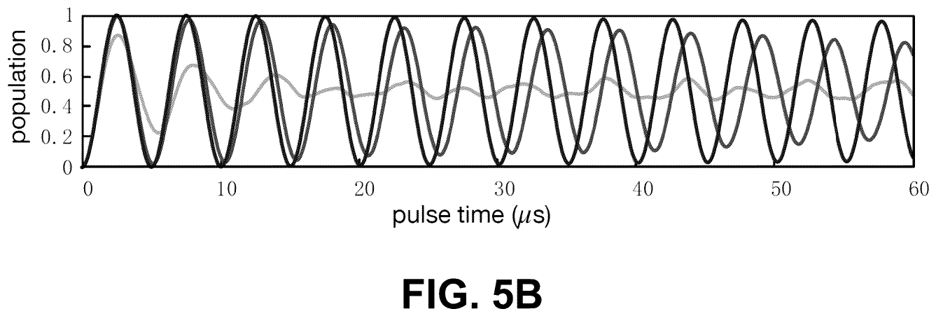

FIG. 5A is a plot comparing produced signal spectra, according to example embodiments. FIG. 5A shows laser spectra with (red and blue) and without (yellow) the feedforward circuit 108 being applied to the laser. The blue (red) data shows the case where an optical fiber delay line (e.g., the optical fiber 112 shown and described with reference to FIG. 1B and having an example length of 30 m) is used (not used) prior to the electro-optic modulator 110. The inset shows the same data over a wider frequency range. The resolution bandwidth is 100 Hz for all the measurements in this plot.

FIG. 5B is a plot comparing simulations of driven two-level atoms, according to example embodiments. FIG. 5B shows simulations of driven two-level atoms under the three laser noise cases from FIG. 5A using a Rabi frequency of Ω=2π×200 kHz, which is near the peak of the servo bump associated with an ECDL laser.

FIG. 6A is a plot comparing devices having different length optical fibers, according to example embodiments. To attempt to quantify the qualities of example embodiments, the spectral density of the feedforward signal is compared, at each frequency, to an example where a feedforward circuit is not included. Hence, the noise power attenuation is less than 0 in spectral regions where the feedforward circuit 108 reduces the noise, and the noise power attenuation is greater than 0 in spectral regions where the feedforward circuit 108 increases the noise. The bandwidth in which the feedforward circuit 108 reduces the noise may depend on the relative delay between the optical and electrical signals. FIG. 6A shows the noise power attenuation for various lengths of the optical fiber 112 (e.g., for lengths of 0 m, 15 m, and 30 m, which correspond to approximately 140 ns, 70 ns, and 0 ns, respectively, of difference between the electrical delay and optical delay). While all three cases show values of noise power attenuation less than 0 below about 1 MHZ, the 0 m and 15 m cases have values greater than 0 beyond 1 MHz before approaching 0. In the 0 m case, the numerical model used based on the circuit transfer function predicts that there will be a dip below 0 near 6 MHz where the relative phase delay is roughly 2π, such that the feedforward can successfully cancel noise. The data does not corroborate this dip, which is believed to be due to the limited noise to cancel at 6 MHz (due to the profile of the servo bump being primarily below 1 MHz). For a 30 m optical fiber length, the data is in agreement with the numerical modeling, which suggests that the relative delay is small, offering optimized performance of the feedforward method. The region where the noise power attenuation is less than 0 is maximized under this condition, and the signal asymptotes to 0, as opposed to first going positive.

FIG. 6B is a plot comparing devices having different length optical fibers, according to example embodiments. To optimize a length of the optical fiber 112 with respect to the introduced optical delay, a figure of merit was defined to be the integrated noise under the noise power attenuation from 0 frequency up to a chosen bandwidth. FIG. 6B shows this figure of merit for several ranges of frequencies. As illustrated, there are minima at a fiber length of 30 m for all frequency ranges shown. This is in agreement with an understanding based on the transfer function of example embodiments, suggesting that there is approximately a 140 ns electrical delay. For a length of 30 m, a propagation time of about 140 ns results for an optical fiber having an index of refraction of 1.44.

As described herein, using the phase noise, a feedforward system following a high-finesse, cavity-locked laser is used to remove the servo bump. Compared with a feedback-based approach, a feedforward system gives more flexibility and advantages for attenuating the phase noise. Firstly, in a feedforward system, the control variable is not error-based and thus there is no stability issue that is pervasive for a closed-loop system. Secondly, the electrical time delay (τₑ) of the phase noise measurement and frequency modulation device can be compensated by introducing the same amount of delay in the optical path. In a closed-loop system, the loop bandwidth of a feedback system is limited by (¼τₑ).

Considering the finite bandwidth and the delay in the system, the transfer function of the feedforward phase noise canceling system can be written as:

$$H ( s ) = 1 - \frac{{e}^{- ( {τ}_{e} - {τ}_{o} ) s}}{1 + \frac{s}{2 π {f}_{3 d B}}}$$

where f_{3dB} is the bandwidth of the feedforward system. The factor e^{-(τ}^{ₑ}^{-τ}^{ₒ}^{)s} describes the phase delay introduced by the fixed optical and electrical time delay. When τₒ=τₑ, the transfer function H(s) gives a noise attenuation factor f_{3dB}²/(f_{3dB}²+f²), which is 0.5 when f=f_{3dB} and gradually approaches 0 for higher frequency. For a system with infinite bandwidth, the feedforward can be understood as a self-heterodyne measurement with the fiber delay to replaced by the overall delay of τₑ−τₒ. The frequency response of the transfer function H(s) under different τₑ−τₒ is shown in FIG. 6A and the dip in the red curve can be understood as the laser phase noise around 6 MHz being canceled by the measurement of the same phase noise around one period (approximately 140 ns) before.

Finally, it is noted that a similar feedforward method may also be employed in phase noise removal for a microwave band oscillator. A sub-sampling phase detector (SSPD) may be used for measuring the phase noise and feed it forward to a variable delay line for canceling the phase noise.

FIG. 6C is a plot comparing devices having different properties, according to example embodiments. The optical fiber 112 can introduce noise due to acoustic and thermal path length fluctuations. Thus, the use of the optical fiber 112 to compensate electrical delay introduces low frequency noise that can be removed with active feedback. FIG. 6C shows beat note spectra similar to those in FIG. 5A, except over a much narrower frequency range. The optimized case (e.g., with an optical fiber length of 30 m) is shown. The inset shows a situation where no optical fiber delay is present. Both the optimized case and the no optical fiber case are also shown with and without a feedforward circuit 108 present. In the inset, there is no apparent difference. FIG. 6C (main body) shows the same two cases, where now the fiber-induced noise is removed by including the feedback circuit 114. Here, the spectra are Fourier limited and there is no apparent broadening due to the optical fiber 112. As illustrated, the peak corresponding to the case where the feedforward is engaged has a higher amplitude than the peak where feedforward is not engaged. This is due to the noise cancellation process that actively transfers the spectral weight of the laser noise back into the coherent peak. The increased amplitude shown here may be comparable with the spectral weight under the servo bumps and the laser power is unchanged during the measurement.

This spectrum may not be a true measure of the laser 102 linewidth since the coherence length is much longer than the path length difference in the interferometer arms. From other data, it is believed that the laser 102 tested has a greater than 1 Hz linewidth.

FIG. 6D is a plot comparing devices having different properties, according to example embodiments. The intensity noise of the laser with and without applying the feedforward was also considered. FIG. 6D shows the intensity noise of the background as well as the laser output 152 in both cases. As illustrated, the case with the feedforward has increased noise within approximately 4 MHz compared to the case without the feedforward applied. We attribute this to residual amplitude modulation (RAM) on the electro-optic modulator 110, in which frequency modulation is partially mapped onto amplitude modulation (typically due to an imperfect input polarization). This problem may be more prevalent with waveguide electro-optic modulators. Hence, these findings may support a decision to use a free-space electro-optic modulator 110. Further improvements to the setup could reduce the measured RAM. Hence, to quantify the significance of this added intensity noise, numerical modeling has been used.

In order to quantitatively evaluate the influence of the laser phase noise on the atomic state dynamics, the Schrödinger equation of a two-level system driven by the time-dependent phase factor ϕ(t) and coupling fluctuation factor ϵ(t) is numerically solved. For zero laser detuning, the Hamiltonian of the system is given by:

$$\hat{H} ( t ) = \frac{[ 1 + ϵ ( t ) ] Ω}{2} {e}^{- i ϕ ( t )} \vert e 〉 〈 g \vert + H . c .$$

where Ω is the Rabi frequency, ϕ(t) and ϵ(t) are the time traces of the laser phase and the field amplitude variation, respectively.

The phase noise may be calculated by the beat signal in FIG. 5A following a standard procedure. Using a measured single-ended phase noise S_{ϕ}(f) (in rad²/Hz), sets of the time trace ϕⁱ(t) for the given laser phase noise can be calculated:

$${ϕ}^{i} ( t ) = {\sum }_{f} \sqrt{2 {S}_{ϕ} ( f ) Δ f} cos ( 2 π ft + {ϕ}_{f}^{i} )$$

where ϕ_{f}ⁱ is the random phase offset of frequency f and phase noise trace i, Δf is the frequency resolution of S_{ϕ}(f). The phase offset is sampled uniformly, ϕ_{f}ⁱ∈[0, 2π).

By the same method, the laser intensity noise trace Δlⁱ(t) with the intensity noise spectrum S₁(f) shown in FIG. 6D can be calculated. Since the Rabi frequency Ω˜\sqrt{I}, ϵ(t) may be determined by \sqrt{[I₀+ΔIⁱ(t)]/I₀}−1, where I₀ is the average laser intensity. Considering the noise is wide-band and small (ΔI«I₀), the approximation

$$\sqrt{[ {I}_{0} + Δ {I}^{i} ( t ) ] / {I}_{0}} - 1 = \frac{1}{2} Δ {I}^{i} ( t ) / {I}_{0}$$

can be used.

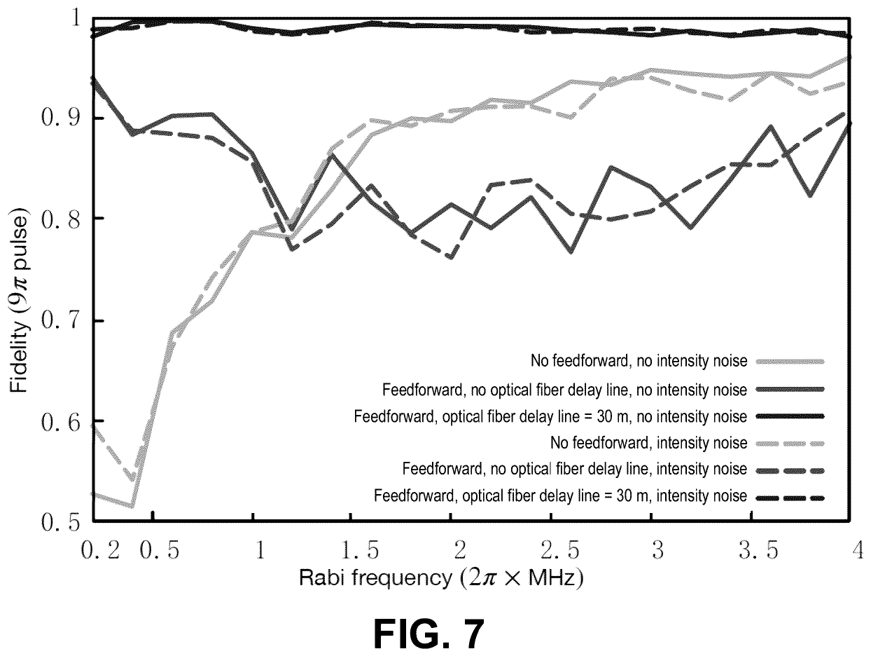

With the calculated time traces ϕⁱ(t) and ϵⁱ(t), the time-dependent Hamiltonians using the Runge-Kutta method may be simulated. The time evolution of the state vector over a series of N=50 trials of the phase noise trace may be averaged. The Rabi dynamics and the corresponding fidelity under different Rabi frequencies are illustrated in FIGS. 5B and 7. It is noted that the intensity noise and phase noise are uncorrelated in this simulation, which may not be 100% reflective of an actual setup. However, this assumption may only amount to a rather small difference since the intensity noise is significantly smaller than the phase noise.

FIG. 7 is a plot comparing devices having different properties, according to example embodiments. A driven two-level atomic system using the measured noise was simulated to gauge the effect of the above-mentioned noise cancellation techniques when applied to atomic dynamics. First, only frequency noise was considered. The cases of the feedforward engaged with both 0 m and 30 m optical fiber length and the feedforward not engaged were considered. FIG. 7 shows the 9π pulse fidelity, which is the fifth maximum population transfer fraction of the Rabi evolution, versus the Rabi frequency used in the simulation. As illustrated, Rabi frequencies in regions of high noise give particularly poor fidelity, and thus these results are qualitatively similar to the inverse of the noise spectra shown in FIG. 5A. FIG. 5B shows time traces of these Rabi evolutions for a Rabi frequency of Ω=2π×200 kHz. Correspondingly, as shown in FIG. 7, the case without feedforward has poor fidelity between 0.2 MHz and about 1 MHz, which then asymptotically approaches unity well beyond the servo bump bandwidth. The case of feedforward with an optical fiber length of 0 m is significantly improved at low frequency, but this improvement is lost beyond about 1.3 MHz where the relative delay time causes the feedforward to degrade the fidelity. The case of feedforward with an optical fiber length of 30 m has excellent fidelity over the entire frequency range since noise is efficiently canceled within the servo bump bandwidth and noise is not added outside this bandwidth.

FIG. 7 also includes simulations with the measured intensity noise from FIG. 6D. Further, both frequency noise and intensity noise for the two cases with feedforward applied has been considered. In practice, it is believed that the frequency noise may be synchronized with the intensity noise, but the two are uncorrelated in the illustrated simulations. It was found that the intensity noise is irrelevant compared to the frequency noise over the entire range of 22 considered. This can be understood by considering the similarity between the amplitude and the phase modulation for small index. We can express a phase-modulated signal with the phase variation defined by Δϕ→0 as sin(ωt+Δϕ)≈sin(ωt)+Δϕ·cos(ωt), where ω is the carrier frequency, and the second term is amplitude-modulated by the phase variation Δϕ. By converting the curves in FIG. 5A into phase noise, it can be shown that the phase noise is always higher than −90 dBc/Hz even for the best configuration (with feedforward and 30 m fiber delay). This phase noise level is still much higher than the intensity noise in FIG. 6D.

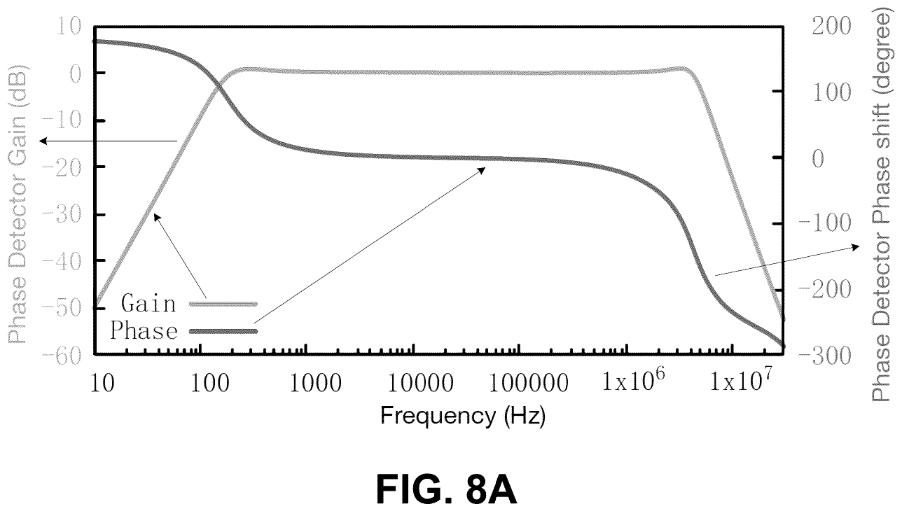

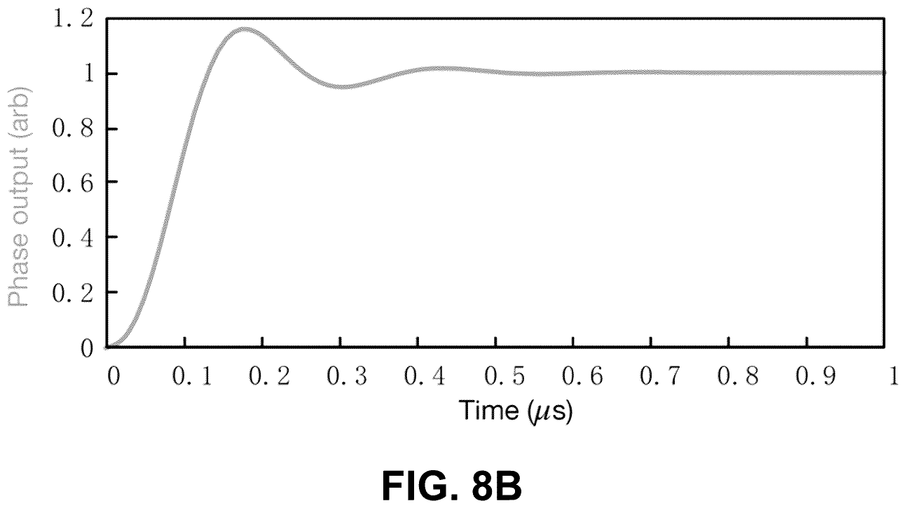

FIG. 8A is a plot of simulated results of a portion of a feedforward circuit, according to example embodiments. FIG. 8A may correspond to a Bode plot of an output of the first portion 108A of the feedforward circuit 108 (e.g., as shown and described above with reference to FIG. 2B) versus the phase variation signal input.

FIG. 8B is a plot of simulated results of a portion of a feedforward circuit, according to example embodiments. FIG. 8B may correspond to a step response of an output of the first portion 108A of the feedforward circuit 108 (e.g., as shown and described above with reference to FIG. 2B).

### V. ALTERNATIVE EXAMPLE SYSTEMS

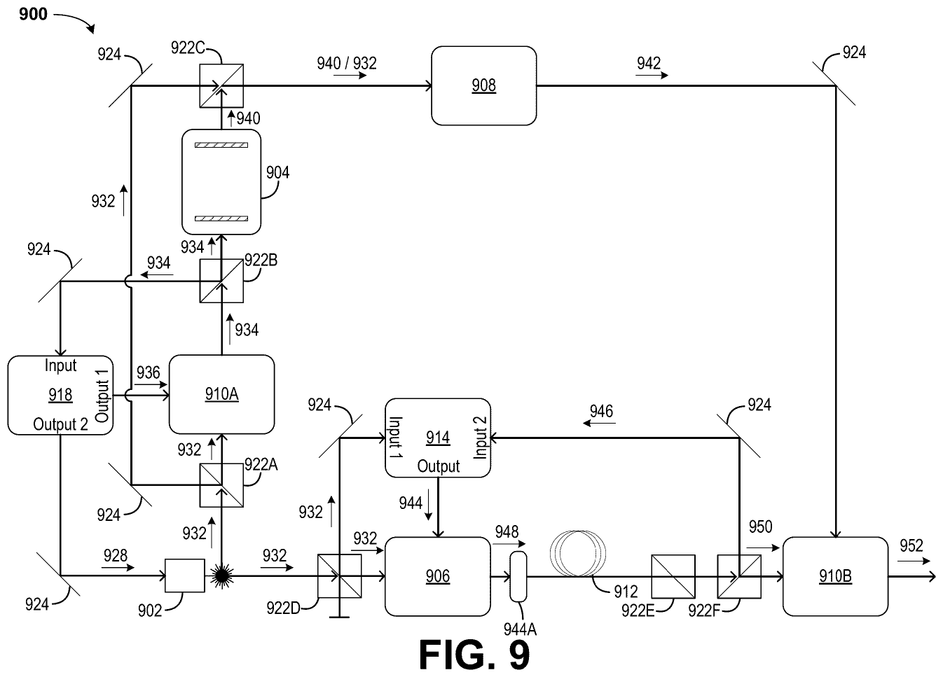

Two devices 100, 150 have been shown and described above with reference to FIGS. 1A-3. It is understood, however, that other devices are also possible and are contemplated herein. For example, FIG. 9 is a schematic diagram of an alternative device 900, according to example embodiments. The device 900 illustrated in FIG. 9 may include components that are similar the components of the device 150 shown and described with reference to FIG. 1B. For example, the device 900 may include a laser 902 (e.g., similar to the laser 102 in FIG. 1B), an optical cavity 904 (e.g., similar to the optical cavity 104 in FIG. 1B), an acousto-optic modulator 906 (e.g., similar to the acousto-optic modulator 106 in FIG. 1B), a feedforward circuit 908 (e.g., similar to the feedforward circuit 108 in FIG. 1B), two electro-optic modulators 910A, 910B (e.g., each similar to the electro-optic modulator 110 in FIG. 1B), an optical fiber 912 (e.g., similar to the optical fiber 112 in FIG. 1B), a feedback circuit 914 (e.g., similar to the feedback circuit 114 in FIG. 1B), multiple beamsplitters 922A, 922B, 922C, 922D, 922E, 922F (e.g., similar to the beamsplitters 122A, 122B, 122C, 122D, 122E in FIG. 1B), and multiple mirrors 924 (e.g., similar to the mirrors 124 in FIG. 1B). However, while many components of the device 900 are similar to (or the same as) the components of the device 150 of FIG. 1B, the device 900 of FIG. 9 may include some additional components not present in the device 150 of FIG. 1B and/or the components of the device 900 may be interconnected in a different fashion than in the device 150 of FIG. 1B.

As illustrated in FIG. 9, the laser 902 (e.g., the TA-SHG PRO laser produced by TOPTICA PHOTONICS) may generate a laser output 932. The laser output 932 may be transmitted to two beamsplitters 922A, 922D. After reaching the beamsplitter 922A, one portion of the laser output 932 may be sent to a first electro-optic modulator 910A and another portion of the laser output 932 may to transmitted to a beamsplitter 922C (e.g., using one or more mirrors 924 to direct the signal).

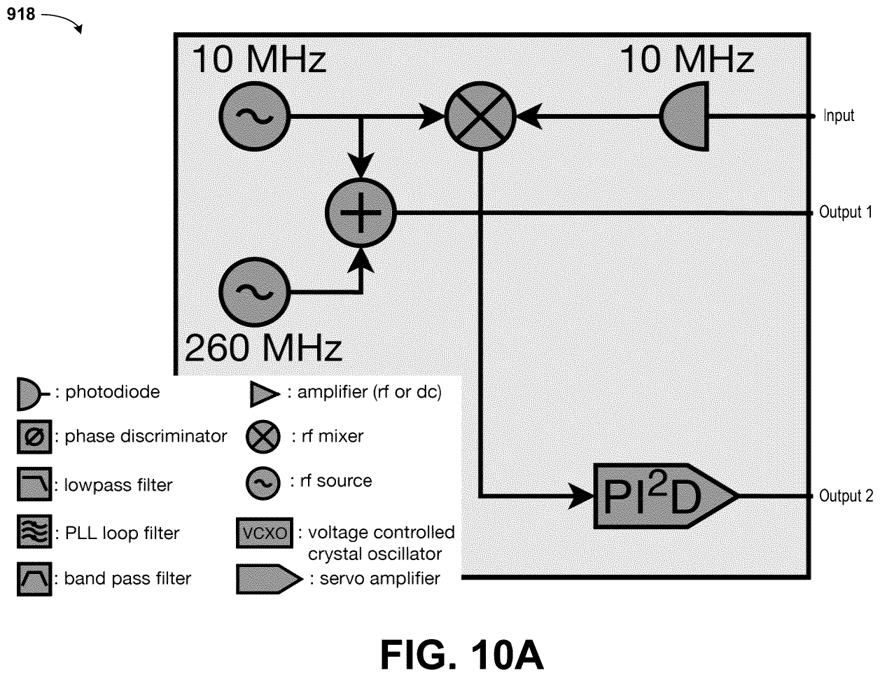

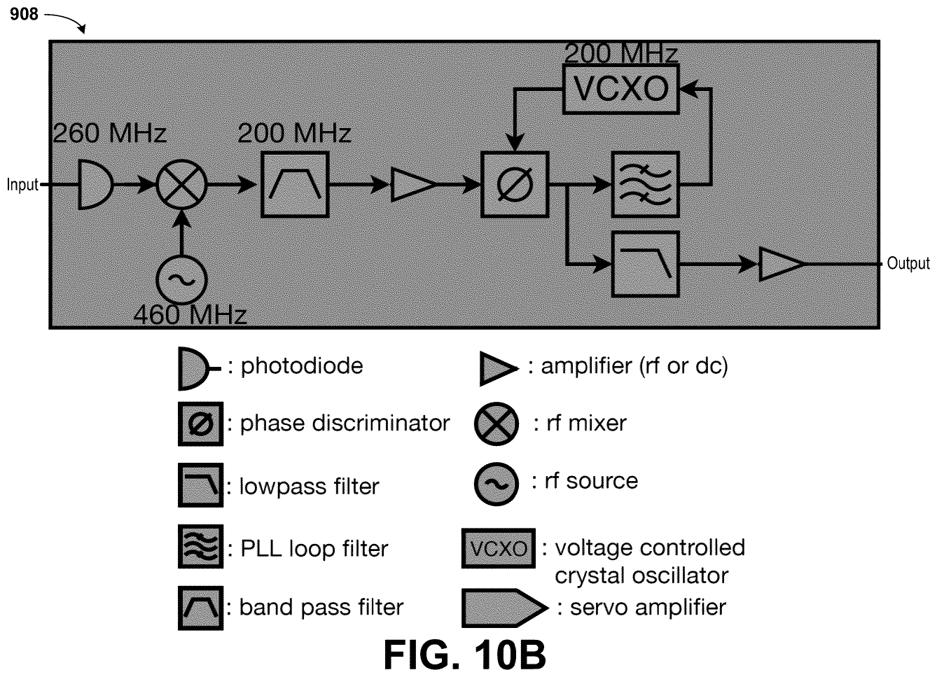

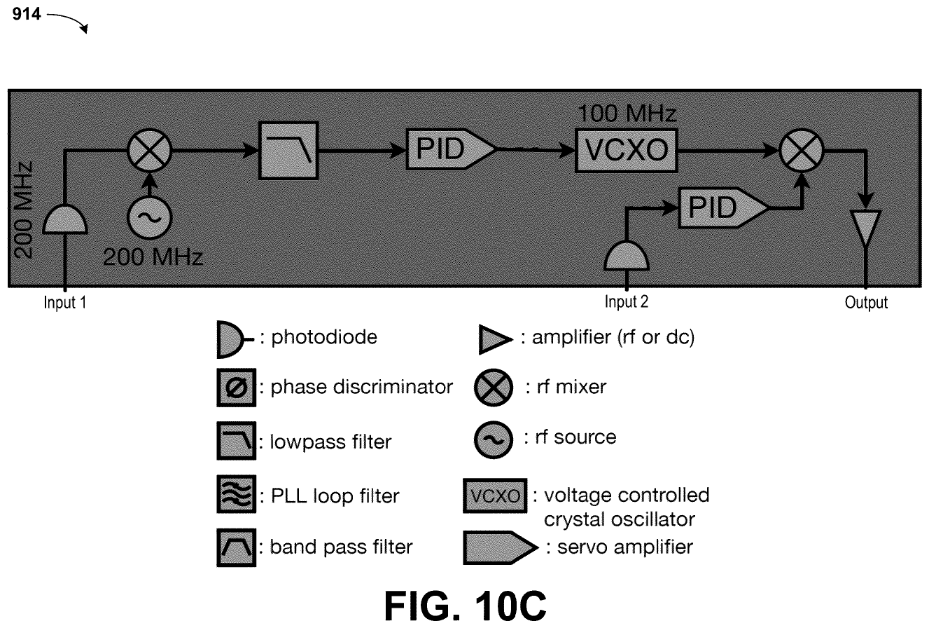

The first electro-optic modulator 910A may modulate the laser output 932 using an offset signal 936 output by a PDH servo 918, thereby generating a modulated signal 934. The offset signal 936 may be locked to a resonant frequency of the optical cavity 904, in some embodiments. After being produced by the first electro-optic modulator 910A, the modulated signal 934 may be transmitted to a beamsplitter 922B. Thereafter, one portion of the modulated signal 934 may be sent to the PDH servo 918 and another portion of the modulated signal 934 may be transmitted to the optical cavity 904. The PDH servo 918 may use the modulated signal 934 to generate a control signal 928 (e.g., a PI²D control signal) that is provided to the laser 902 (e.g., using one or more mirrors to direct the control signal 928). The PDH servo 918 is shown and described further below with reference to FIG. 10A.

The portion of the modulated signal 934 that is received by the optical cavity 904 may be filtered by the optical cavity 904 to reduce high-frequency noise, resulting in a reference signal 940. The reference signal 940 and the laser output 932 (e.g., the portion of the laser output 932 that optically bypassed the optical cavity 904) may then interfere at the beamsplitter 922C and the combination may be transmitted to the feedforward circuit 908. The feedforward circuit (described further below with reference to FIG. 10B) may generate a feedforward signal 942 based on the reference signal 940, and the feedforward signal 942 may be provided to a second electro-optic modulator 910B (e.g., using one or more mirrors 924 to direct the feedforward signal 942).

After reaching the beamsplitter 922D, a portion of the laser output 932 (e.g., a frequency doubled portion of the laser output 932) may be provided to the feedback circuit 914. Another portion of the laser output 932 may be provided to the acousto-optic modulator 906. The acousto-optic modulator 906 may produce a modulated signal 948 using a correction signal 944 provided by the feedback circuit 914 (described further below with reference to FIG. 10C). The modulated signal 948 may be transmitted through a faraday rotator 944A into the optical fiber 912 (e.g., an optical fiber used to introduce optical delay) and then to a beamsplitter 922F (e.g., via another beamsplitter 922E). Upon reaching the beamsplitter 922F, the modulated signal 948 may be split into a feedback signal 946 and a delayed laser signal 950. The feedback signal 946 may be provided to the feedback circuit 914 (e.g., and used with the laser output 932 to produce the correction signal 944). In some embodiments, the feedback signal 946 may be usable by the feedback circuit 914 to measure frequency drifts associated with propagation of the laser output 932 (e.g., via the modulated signal 948) through the optical fiber 912. Finally, the second electro-optic modulator 910B may use the feedforward signal 942 to modulate the delayed laser signal 950 in order to produce an output signal 952 (e.g., to remove a servo noise bump).

FIG. 10A is an illustration of a PDH servo (e.g., the PDH servo 918 shown and described with reference to FIG. 9). As shown by the combination of FIGS. 9 and 10A, the PDH servo 918 may lock a 260 MHz sideband modulated by the first electro-optic modulator 910A to the optical cavity 904. As shown in FIG. 10A, an rf source of 10 MHz and an rf source of 260 MHz may be added together to generate output 1 (e.g., which is sent to the first electro-optic modulator 910A as the offset signal 936, as shown in FIG. 9). Further, a photodiode (e.g., a 10 MHz photodiode) may detect a signal (e.g., the modulated signal 934, as shown in FIG. 9) at the input. This received signal is mixed with the generated 10 MHz at an rf mixer and then provided to a PI²D amplifier in order to generate output 2 (e.g., which is sent to the laser 902 as the control signal 928, as shown in FIG. 9).

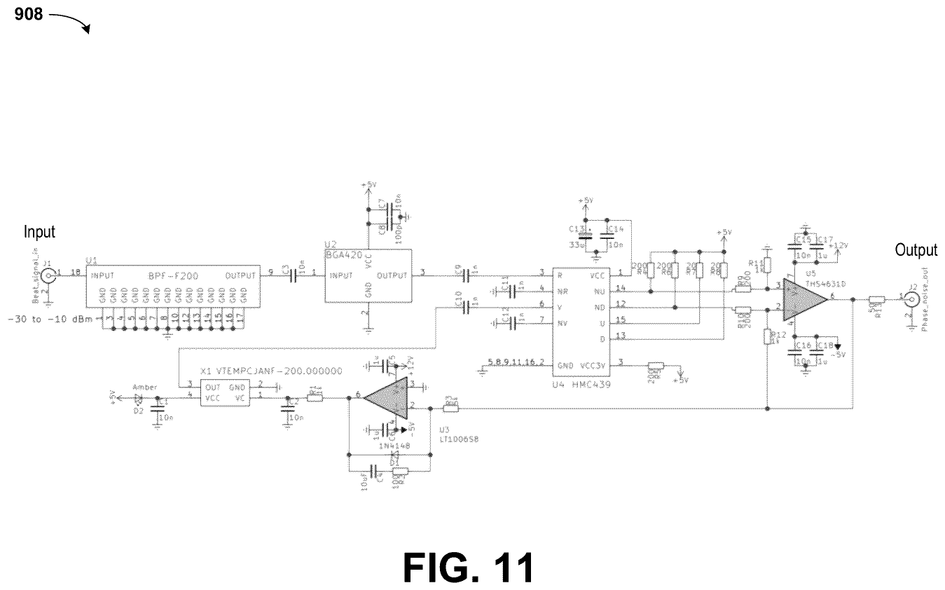

FIG. 10B is an illustration of a feedforward circuit (e.g., the feedforward circuit 908 shown and described with reference to FIG. 9). As shown by the combination of FIGS. 9 and 10B, the feedforward circuit 908 may use a photodiode (e.g., a 260 MHz photodiode) to detect a signal (e.g., the laser output 932 and/or the reference signal 940) at an input of the feedforward circuit 908. The detected signal may be mixed with a signal from a 460 MHz rf source at an rf mixer and then sent through a 200 MHz band pass filter. Thereafter, the filtered signal may be amplified (e.g., by an rf amplifier) and sent through a phase discriminator. The output of the phase discriminator may be split into two portions, one of which is fed through a PLL loop filter and then through a voltage controlled crystal oscillator (e.g., oscillating at 200 MHz) and back to the phase discriminator, whereas the other portion is fed through a low pass filter and then through an amplifier (e.g., an rf amplifier) to generate a feedforward signal (e.g., the feedforward signal 942 shown and described with reference to FIG. 9) at an output. In some embodiments, the gain of one or both of the amplifiers in the feedforward circuit 908 may be tuned to maximize a Rabi frequency of an atomic clock transition. A detailed schematic of an example feedforward circuit is shown and described below with reference to FIG. 11.

FIG. 10C is an illustration of a feedback circuit (e.g., the feedback circuit 914 shown and described with reference to FIG. 9). As shown by the combination of FIGS. 9 and 10C, the feedback circuit 914 may use a photodiode (e.g., a 200 MHz photodiode) to detect a signal (e.g., the laser output 932) at input 1. The detected signal may be mixed with a 200 MHz signal generated by an rf source at an rf mixer and then provided to a low pass filter. The filtered signal may then be provided to a servo amplifier (e.g., a PID amplifier) and then to a voltage controlled crystal oscillator (e.g., oscillating at 100 MHz). After passing through the voltage controlled crystal oscillator, the signal may be mixed with a secondary signal at an rf mixer. The secondary signal may be a signal (e.g., feedback signal 946) detected by a photodiode at input 2 and amplified by a servo amplifier (e.g., a PID amplifier) before being provided to the rf mixer. The mixture of the signal from the voltage controlled crystal oscillator with the secondary signal may be amplified by an amplifier (e.g., an rf amplifier) and then provided as an output (e.g., provided as the correction signal 944 to the acousto-optic modulator 906).

FIG. 11 is a detailed schematic illustration of portions of an example feedforward circuit (e.g., the feedforward circuit 908 shown and described with reference to FIGS. 9 and 10B). The beat signal detected from the photodiode (e.g., the photodiode illustrated in FIG. 10B) may first be amplified and then mixed with the local oscillator to generate a 200 MHz tone with a signal level between −30 and −10 dBm. This signal may then be sent through the circuit shown in the FIG. 11. BPF-F200 may be a 200 MHz band pass filter with 10 MHz bandwidth produced by MINI-CIRCUITS that removes the rf leakage from the local oscillator and other high harmonics generated by the mixer.

After the filter, the signal may be amplified to a desired level by another low noise amplifier (e.g., INFINEON TECHNOLOGIES BGA420). After the phase detector, a fast differential amplifier (e.g., TEXAS INSTRUMENTS THS4631) converts the differential current output to a single-ended voltage signal that is proportional to the phase difference between the two inputs of the phase detector. The differential amplifier shown in FIG. 11 may give a bandwidth close to 40 MHz, in some embodiments. The remaining parts of the circuit may be similar to the illustrations of FIGS. 2B and 2C.

In some embodiments, the input band pass filter may limit the feedforward bandwidth to 5 MHz. However, it may be useful to increase the bandwidth of the differential amplifier. For example, an ideal feedforward circuit with 5 MHz bandwidth may remove only 50% of the phase noise at 5 MHz, but may remove 98.5% of the same noise for a 40 MHz bandwidth.

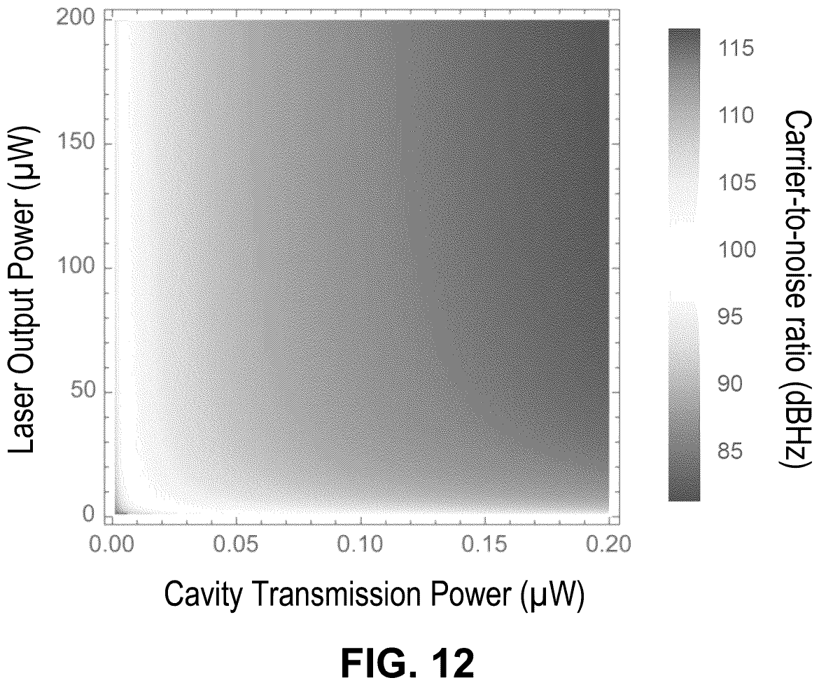

FIG. 12 is a simulation of SNR (or, more accurately, carrier-to-noise ratio, as measured in dBHz) for an example device similar to the device 900 illustrated in FIG. 9, according to example embodiments.

The transmitted power of the optical cavity 904 (e.g., at 1156 nm) may be relatively small (e.g., around 200 nW). Further, only ˜90 nW of the optical cavity's transmission may be collected by the photodiode (e.g., the photodiode of the feedforward circuit 908) after beamsplitter 922C. Thus, it may be useful to understand whether the device 900 is shot noise limited and any associated limitations with the feedforward scheme of the device 900. The main sources of the noise in the device 900 are the photodiode's shot noise and the thermal noise of an associated amplifier (e.g., an amplifier of the feedforward circuit 908). This SNR limits the noise suppression factor of the feedforward setup. The noise figure of the amplifier (e.g., a MINI-CIRCUITS MAR-8A+) may be 3.1 dB and the quantum efficiency of the photodiode (e.g., an ADVANCED PHOTONIX SD0003-3111-111) may be around 0.8. Using the capacitance of the photodiode (e.g., 1.5 pF), the electrical noise of the photodiode at 260 MHz may be calculated. Adding the shot noise together with the technical noise results in the plot of FIG. 12, which shows the theoretical carrier-to-noise ratio of the beat signal under different power configurations of optical cavity transmission beam and laser output beam. As shown, the device 900 is shot noise limited within standard operating regions.

In one example implementation of the device 900 of FIG. 9, the laser output power may be ˜100 μW before the photodiode, which gives a theoretical carrier to noise density ratio of about 112 dBHz. In experiments, a beat signal to background noise ratio about 68 dB for 1000 Hz resolution bandwidth was measured, which is equivalent to about 98 dBHz. This means the minimum single-sideband (SSB) phase noise is comparable to or larger than-98 dBc/Hz, which is significantly smaller than the peak of the servo noise bump (e.g., around-60 dBc/Hz).

### VI. CONCLUSION

The present disclosure is not to be limited in terms of the particular embodiments described in this application, which are intended as illustrations of various aspects. Many modifications and variations can be made without departing from its scope, as will be apparent to those skilled in the art. Functionally equivalent methods and apparatuses within the scope of the disclosure, in addition to those described herein, will be apparent to those skilled in the art from the foregoing descriptions. Such modifications and variations are intended to fall within the scope of the appended claims.

The above detailed description describes various features and operations of the disclosed systems, devices, and methods with reference to the accompanying figures. The example embodiments described herein and in the figures are not meant to be limiting. Other embodiments can be utilized, and other changes can be made, without departing from the scope of the subject matter presented herein. It will be readily understood that the aspects of the present disclosure, as generally described herein, and illustrated in the figures, can be arranged, substituted, combined, separated, and designed in a wide variety of different configurations.

With respect to any or all of the message flow diagrams, scenarios, and flow charts in the figures and as discussed herein, each step, block, operation, and/or communication can represent a processing of information and/or a transmission of information in accordance with example embodiments. Alternative embodiments are included within the scope of these example embodiments. In these alternative embodiments, for example, operations described as steps, blocks, transmissions, communications, requests, responses, and/or messages can be executed out of order from that shown or discussed, including substantially concurrently or in reverse order, depending on the functionality involved. Further, more or fewer blocks and/or operations can be used with any of the message flow diagrams, scenarios, and flow charts discussed herein, and these message flow diagrams, scenarios, and flow charts can be combined with one another, in part or in whole.

A step, block, or operation that represents a processing of information can correspond to circuitry that can be configured to perform the specific logical functions of a herein-described method or technique. Alternatively or additionally, a step or block that represents a processing of information can correspond to a module, a segment, or a portion of program code (including related data). The program code can include one or more instructions executable by a processor for implementing specific logical operations or actions in the method or technique. The program code and/or related data can be stored on any type of computer-readable medium such as a storage device including random-access memory (RAM), a disk drive, a solid state drive, or another storage medium.

The computer-readable medium can also include non-transitory computer-readable media such as computer-readable media that store data for short periods of time like register memory and processor cache. The computer-readable media can further include non-transitory computer-readable media that store program code and/or data for longer periods of time. Thus, the computer-readable media may include secondary or persistent long term storage, like read-only memory (ROM), optical or magnetic disks, solid state drives, compact-disc read-only memory (CD-ROM), for example. The computer-readable media can also be any other volatile or non-volatile storage systems. A computer-readable medium can be considered a computer-readable storage medium, for example, or a tangible storage device.

Moreover, a step, block, or operation that represents one or more information transmissions can correspond to information transmissions between software and/or hardware modules in the same physical device. However, other information transmissions can be between software modules and/or hardware modules in different physical devices.

The particular arrangements shown in the figures should not be viewed as limiting. It should be understood that other embodiments can include more or less of each element shown in a given figure. Further, some of the illustrated elements can be combined or omitted. Yet further, an example embodiment can include elements that are not illustrated in the figures.

While various aspects and embodiments have been disclosed herein, other aspects and embodiments will be apparent to those skilled in the art. The various aspects and embodiments disclosed herein are for purpose of illustration and are not intended to be limiting, with the true scope being indicated by the following claims.

What is claimed:

1. A device comprising:
an optical cavity exhibiting a resonant optical frequency;
a laser that is optically coupled to the optical cavity, wherein an output of the laser is locked to the resonant optical frequency, and wherein a first portion of the laser output is transmitted through the optical cavity to filter out high-frequency noise from the first portion of the laser output to generate a modified signal;
an acousto-optic modulator configured to interfere a second portion of the laser output with a first portion of the modified signal at a beat frequency to generate a reference signal;
a feedforward circuit configured to receive a first portion of the reference signal and generate a feedforward signal, wherein generating the feedforward signal comprises attenuating frequencies from the first portion of the reference signal that were present in the first portion of the modified signal but not present in the second portion of the laser output; and
an electro-optic modulator configured to interfere a second portion of the reference signal with a second portion of the modified signal using the feedforward signal to generate an output signal.

2. The device of claim 1, further comprising an optical fiber,
wherein the electro-optic modulator is configured to receive the second portion of the reference signal via the optical fiber, and
wherein the optical fiber is configured to introduce a time delay that corresponds to an electrical delay of the feedforward circuit.

3. The device of claim 2, further comprising a feedback circuit configured to:
receive a first portion of the output signal;
measure frequency drifts associated with propagation of the second portion of the reference signal through the optical fiber;
generate a correction signal based on the measured frequency drifts; and
provide the correction signal to the acousto-optic modulator.

4. The device of claim 2, wherein the optical fiber is spooled such that an input end of the optical fiber is separated from an output end of the optical fiber by a distance that is less than 10% of a total length of the optical fiber.

5. The device of claim 2,
wherein an input end of the optical fiber is separated from an output end of the optical fiber by a distance that is greater than 10% of a total length of the optical fiber,
wherein a reflection from the output end of the optical fiber is used in an interferometer, and
wherein the interferometer generates a correction signal usable to correct for noise arising from signal propagation through the optical fiber.

6. The device of claim 1, further comprising a frequency multiplier configured to apply a multiplication factor to the output signal,
wherein the frequency multiplier comprises a frequency doubler, a frequency quadrupler, a sum frequency mixer, or a difference frequency mixer, and
wherein generating the feedforward signal comprises applying the multiplication factor to the first portion of the reference signal.

7. The device of claim 6, further comprising an optical fiber,
wherein the electro-optic modulator is configured to receive the second portion of the reference signal via the optical fiber,
wherein the optical fiber is configured to introduce a time delay that corresponds to an electrical delay of the feedforward circuit upstream of the frequency multiplier applying the multiplication factor to the output signal, and
wherein applying the multiplication factor to the output signal produces a signal having an ultraviolet wavelength.

8. The device of claim 1, wherein the beat frequency is between 150 MHz and 250 MHz.

9. The device of claim 1, wherein the electro-optic modulator comprises a free-space electro-optic modulator.

10. The device of claim 1, wherein the laser comprises an external cavity diode laser.

11. The device of claim 1, wherein the electro-optic modulator comprises a cathode-ray tube driver.

12. The device of claim 1, wherein the optical cavity has a finesse of greater than 100,000.

13. The device of claim 1, wherein attenuating frequencies from the first portion of the reference signal that were present in the first portion of the modified signal but not present in the second portion of the laser output comprises attenuating only frequencies above 200 Hz.

14. A method comprising:
coupling a laser to an optical cavity, wherein the optical cavity exhibits a resonant optical frequency;
locking an output of the laser to the resonant optical frequency;
transmitting a first portion of the laser output through the optical cavity to filter out high-frequency noise from the first portion of the laser output to generate a modified signal;
interfering, by an acousto-optic modulator, a second portion of the laser output with a first portion of the modified signal at a beat frequency to generate a reference signal;
receiving, by a feedforward circuit, a first portion of the reference signal;
generating, by the feedforward circuit, a feedforward signal, wherein generating the feedforward signal comprises attenuating frequencies from the first portion of the reference signal that were present in the first portion of the modified signal but not present in the second portion of the laser output; and
interfering, by an electro-optic modulator using the feedforward signal, a second portion of the reference signal with a second portion of the modified signal to generate an output signal.

15. A device comprising:
an optical cavity exhibiting a resonant optical frequency;
a laser configured to output a laser signal;
a first modulator configured to modulate a first portion of the laser signal using an offset signal at a beat frequency to generate a modulated signal, wherein the modulated signal is transmitted through the optical cavity to filter out high-frequency noise from the modulated signal to generate a reference signal, and wherein the offset signal is locked to the resonant optical frequency;
a feedforward circuit configured to receive the reference signal and generate a feedforward signal, wherein generating the feedforward signal comprises attenuating frequencies from the reference signal that were present in the modulated signal but not present in a second portion of the laser signal that optically bypassed the first modulator and the optical cavity; and
a second modulator configured to modulate a third portion of the laser signal using the feedforward signal to generate an output signal.

16. The device of claim 15, wherein each of the first modulator and the second modulator comprises an electro-optic modulator.

17. The device of claim 15, further comprising an optical fiber,
wherein the second modulator is configured to receive the third portion of the laser signal via the optical fiber, and
wherein the optical fiber is configured to introduce a time delay that corresponds to an electrical delay of the feedforward circuit.

18. The device of claim 17, further comprising:
a third modulator configured to provide adjustments to the third portion of the laser signal prior to the second modulator modulating the third portion of the laser signal; and
a feedback circuit configured to:
measure frequency drifts associated with propagation of the third portion of the laser signal through the optical fiber;
generate a correction signal based on the measured frequency drifts, wherein the correction signal is usable by the third modulator to account for noise resulting in the third portion of the laser signal during propagation through the optical fiber; and
provide the correction signal to the third modulator.

19. The device of claim 15, wherein the third modulator comprises an acousto-optic modulator.

20. The device of claim 15, wherein the feedforward circuit comprises a band pass filter.
